(19) United States
(12) Patent Application Publication
(10) Pub. No.: US 2010/0081237 A1
(43) Pub. Date: Apr. 1, 2010

(54) Integrated Circuit Assemblies and Methods for Encapsulating a Semiconductor Device

(75) Inventors: Tom Sheau Wong, Singapore (SG); Tze Wei Lim, Singapore (SG); Adrianus J.P. van Haasteren, Singapore (SG)

Correspondence Address: Kathy Manke;Avago Technologies Limited, 4380 Ziegler Road, Fort Collins, CO, 80525, US

(73) Assignee: AVAGO TECHNOLOGIES FIBER IP (SINGAPORE) PTE. LTD., Singapore (SG)

(21) Appl. No.: 12/242,111

(22) Filed: Sep. 30, 2008

(51) Int. Cl. H01L 21/00

(52) U.S. Cl. 438/127; 257/E21.001

(57) ABSTRACT

A seal is formed by compressing a cured layer of a composition applied on a substrate. The composition is any liquid, liquefiable, or mastic, which, after application to a surface, is converted or cured to a compressible solid film. The composition includes a flexible polymer as a binding material. The layer on the substrate eliminates the need for a gasket on a contact surface of a mold. The contact surface of the mold compresses the layer during an encapsulation process. The layer remains on the substrate in a finished product. A minimum separation or wall thickness of the mold is defined by the material properties of the mold. The seal eliminates yield loss due to leakage of an encapsulant and reduces maintenance costs associated with the procurement and repeated installation of gaskets on mold tooling.

### BACKGROUND

Integrated circuits are typically formed into packages, with the packages then being mounted or otherwise connected to other substrates and devices. Many different packaging methods and devices exist for integrated circuits. One exemplary package includes a semiconductor that is attached to another circuit substrate, for example a printed circuit board. The printed circuit board is typically fabricated with conductive traces formed thereon in desired patterns. A layer of a material with properties of an electrical insulator commonly referred to as a solder mask is formed on the circuit substrate above the conductive traces. Such electrically insulating layers are typically patterned to provide access at designated locations to the conductive traces on the surface of the substrate. The solder mask typically prevents solder bridging on the circuit side of the assembly. The semiconductor is typically mounted to the circuit substrate by being adhered to the solder mask with a die attach adhesive. Conductive wire or other bonding is then performed to connect the circuits of the semiconductor with the circuits on the substrate.

In an exemplary packaging process, an insulative material is applied to one side of the substrate over the semiconductor and the underlying solder mask to encapsulate the semiconductor. Such a package can be formed by a transfer molding process whereby a mold having a void or mold cavity is placed against the circuit substrate and an encapsulating material or compound is caused to flow therein. Thereafter, the encapsulating material or encapsulant is allowed to cure or harden and the mold is removed.

FIG. 1A illustrates a cross-sectional view of a conventional mold 10 in close proximity to a substrate 40. The substrate 40 is arranged with a mounting surface 43 and an opposing surface 45. The mounting surface 43 supports a semiconductor device 30 attached to the substrate 40. The semiconductor device 30 is mechanically attached, electrically attached, or both to the substrate 40 as known in the art.

The mold 10 is arranged with a channel 12 in a member 11 that faces the substrate 40. An elastic gasket 20 is fixed to a contact surface 14 in the channel 12. The mold 10 is arranged to form a void or cavity 18 of appropriate dimensions to surround the semiconductor device 30.

During a molding procedure, as illustrated in FIG. 1B, the mold 10 and the substrate 40 compress the elastic gasket 20. A left-side channel wall and a right-side channel wall constrain the gasket 20 from lateral movement (i.e., movement along the mounting surface 43 beyond the channel 12. Under compression, the elastic gasket 20 fills any voids in the contact surface 14 and the adjacent portions of the mounting surface 43 of the substrate 40 to prevent the flow or transfer of an encapsulating material or compound from the cavity 18 onto the mounting surface 43. The molding process exposes the elastic gasket 20 to temperature and pressure cycles that degrade the gasket 20 and the integrity of the seal.

The above-described degradation leads to lower yields due to leakage of the encapsulant between the mold 10 and the substrate 40. As a direct result of such failures of the elastic gasket 20 to contain the encapsulant, productivity decreases and maintenance costs increase with each subsequent repair or replacement of the elastic gasket 20.

### SUMMARY

An embodiment of an assembly including an encapsulated semiconductor device is prepared by a process comprising the steps of attaching a semiconductor device to a substrate having a mounting surface and an opposing surface, identifying a contact surface of a mold, the contact surface defining a perimeter of a cavity, generating a pattern having an opening arranged to receive the contact surface when the pattern is in registration with the contact surface, using the pattern to apply a composition to the mounting surface of the substrate, wherein the composition cures to form a compressible layer, arranging the mold and the substrate such that the contact surface compresses the layer to form a seal, filling at least a portion of the volume of the cavity with an encapsulant, permitting the encapsulant to cure and removing the mold from the substrate.

An embodiment of a method for encapsulating a semiconductor device on a substrate includes the steps of applying a composition that cures to form a compressible layer on a mounting surface of a substrate, attaching a semiconductor device to the mounting surface of the substrate, providing a mold having a contact surface that defines a cavity, arranging the mold and the substrate such that the contact surface compresses the layer to form a seal along a perimeter of the cavity, filling at least a portion of the volume of the cavity with an encapsulant, permitting the encapsulant to cure and removing the mold from the substrate.

An embodiment of a method for encapsulating semiconductor devices on a substrate includes the steps of applying a composition to a surface of the substrate, the composition forming a layer, attaching semiconductor devices on the surface of the substrate, arranging a mold forming at least a first cavity and a second cavity in proximity to the substrate such that a contact surface of the mold compresses the layer to enclose respective volumes defined by the first and second cavities and that surrounds respective first and second semiconductor devices attached to the substrate, filling at least a portion of the respective volumes of the first and second cavities with an encapsulant, curing the encapsulant; and removing the mold from the surface of the substrate.

An embodiment of an electro-optical assembly is prepared by a process comprising the steps of applying a composition to a surface of the substrate, the composition forming a layer, arranging a mold forming at least a first cavity and a second cavity in proximity to the substrate such that a contact surface of the mold compresses the layer to enclose respective volumes defined by the first and second cavities and that surrounds respective first and second semiconductor devices attached to the substrate, filling at least a portion of the respective volumes of the first and second cavities with an encapsulant, curing the encapsulant and removing the mold from the surface of the substrate.

An embodiment of a memory device is prepared by a process comprising the steps of applying a composition to a surface of the substrate, the composition curing to form a layer, arranging a mold forming at least a first cavity and a second cavity in proximity to the substrate such that a contact surface of the mold compresses the layer to enclose respective volumes defined by the first and second cavities and that surrounds respective first and second semiconductor devices attached to the substrate, filling at least a portion of the respective volumes of the first and second cavities with an encapsulant, curing the encapsulant and removing the mold from the surface of the substrate.

The figures and detailed description that follow are not exhaustive. The disclosed embodiments are illustrated and described to enable one of ordinary skill to make and use the integrated circuit assemblies and methods for encapsulating a semiconductor device. Other embodiments, features and advantages of the assemblies and methods will be or will become apparent to those skilled in the art upon examination of the following figures and detailed description. All such additional embodiments, features and advantages are within the scope of the assemblies and methods as defined in the accompanying claims.

### BRIEF DESCRIPTION OF THE FIGURES

The integrated circuit assemblies and methods for encapsulating a semiconductor device can be better understood with reference to the following figures. The elements and features within the figures are not necessarily to scale, emphasis instead being placed upon clearly illustrating the principles of forming a seal for encapsulating a semiconductor device. Moreover, in the figures, like reference numerals designate corresponding parts throughout the different views.

FIGS. 1A and 1B are cross-sectional views illustrating a conventional mold process that uses a gasket to form a seal.

FIGS. 2A and 2B are cross-sectional views illustrating an embodiment of a mold apparatus in accordance with a novel method for encapsulating a semiconductor device.

FIGS. 3A and 3B are a cross-sectional view and a bottom-plan view, respectively, of an embodiment of a multiple cavity mold in accordance with an alternative method for encapsulating semiconductor devices.

FIG. 4A is a top-plan view of an embodiment of a pattern.

FIG. 4B is a top-plan view of an embodiment of a substrate of an electro-optical sub-assembly modified by the pattern introduced in FIG. 4A.

FIG. 5 is a top-plan view of an embodiment of an improved memory module.

FIG. 6A is a partial cross-sectional view of a wall of a conventional mold.

FIG. 6B is a partial cross-sectional view of walls of adjacent molds.

FIG. 7 is a flow diagram illustrating an embodiment of a method for encapsulating a semiconductor device.

FIG. 8 is a flow diagram illustrating an embodiment of a method for encapsulating semiconductor devices.

### DETAILED DESCRIPTION

Embodiments of integrated circuit assemblies include a layer applied to a mounting surface of a substrate. The layer is compressible and when a suitably arranged mold contacts the layer, the layer is compressed. The compressed layer forms a temporary seal at the intersection of a contact surface of the mold and the mounting surface of the substrate by filling any discontinuities in the contact surface and the mounting surface of the substrate.

The layer is added during fabrication of the substrate. The layer is formed by applying a composition on the substrate. The composition cures and forms a solid but compressible layer on the surface of the substrate. The layer remains with the substrate and the final assembly after a molding or encapsulation procedure. In this way, a separate and new seal is formed for each molding cycle.

The layer is applied by coating or otherwise applying a composition to select portions of a mounting surface of a circuit substrate. Portions of the mounting surface (including one or more circuit traces or other circuit elements) that are not selected to receive the coating are masked by arranging a stencil or silk screen in registration with a semiconductor device or other features of the circuit substrate and introducing the composition to the openings in the stencil or silk screen. The composition is any liquid, liquefiable compound, or mastic, which after application to a substrate in a thin layer is converted or cured to a compressible solid film. Heretofore, liquid compositions with dyes, commonly referred to as paint, have been applied via a silk screen process to printed circuit boards in a contrasting color to aid in the visual identification of source, circuit elements, hazards, manufacturing details, etc.

The improved integrated circuit assembly includes a compressible layer applied in one or more contiguous layers on a surface of a circuit substrate. The contiguous layers surround a semiconductor device that is to be encapsulated. The composition, which forms the layer, includes a flexible polymer as a binding material, such as, an acrylic resin, polyurethane, or polyester. In addition, the composition may contain one or more pigments in a desired ratio to distinguish the resulting compressible layer or layers from other “information only” labels applied to the circuit substrate.

The one or more contiguous layers may vary in thickness as well as compound characteristics in accordance with one or both of mold design and molding process parameters. Mold processing parameters include, temperature, pressure, time, encapsulant, among others. For example, during mold development, the thickness of the layer may be increased incrementally using a fixed step, or steps of varying thickness and compound characteristics for that matter, until the total thickness of the layer results in a successful seal between the circuit substrate and the mold for a particular molding process. By way of further example, the thickness of the compressible layer may be controlled by applying the composition with a stencil or silk screen with a known thickness to form a base layer. Once the base layer has cured to form a compressible solid film, subsequent layers may be applied on top of the base layer. Statistical analysis can be applied to identify a probability of reaching a desired yield for a particular thickness of the layer(s) for a given molding process.

The illustrated embodiments include single and double cavity molds for simplicity of illustration and clarity of description. The improved integrated circuit assemblies and methods for encapsulating a semiconductor device are not so limited. For example, a multiple cavity mold may be arranged with an array of cavities to encapsulate correspondingly arranged semiconductors attached to a circuit substrate. Furthermore, each individual cavity of a multiple cavity mold may be arranged to encapsulate any number of semiconductor devices as may be desired. The arrangements may include unique arrangements among the various members of a mold array or patterns of repeating arrangements as may be desired.

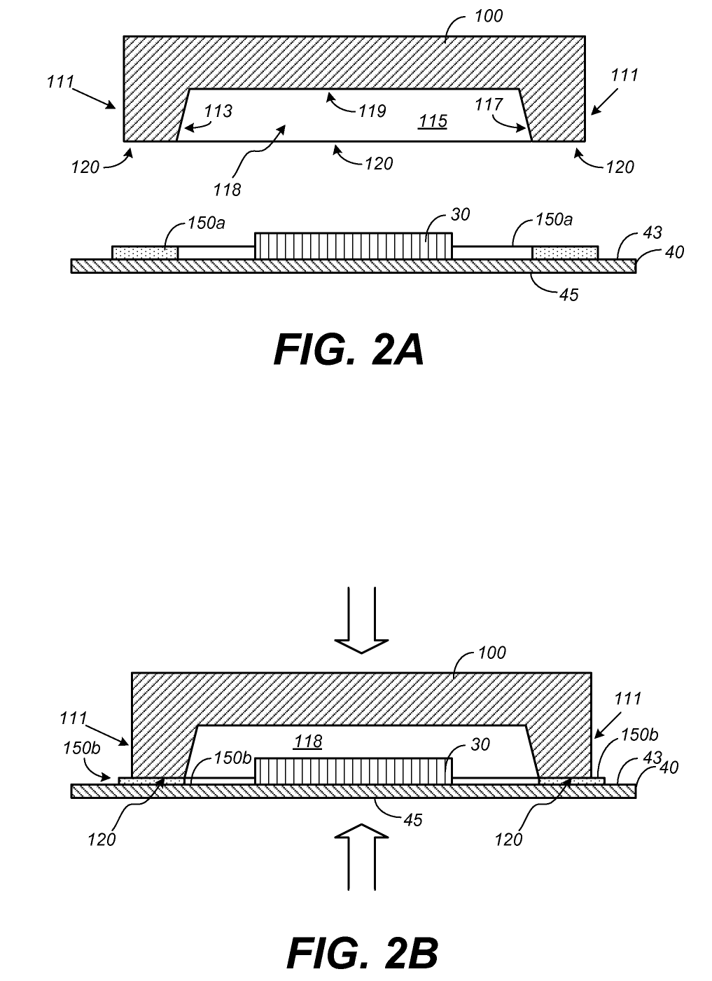

Reference is now directed to FIGS. 2A and 2B, which illustrate an embodiment of an improved mold 100. FIG. 2A shows the mold 100 in a cross-sectional view separate from the substrate 40. FIG. 2B shows the mold in contact with a layer 150b applied on the mounting surface 43 of the substrate 40.

As shown in FIG. 2A, a single-cavity mold 100 is arranged with a member 111 that faces the substrate 40. The mold 100 can be constructed from any material or compound that retains its shape and strength under expected conditions in a molding process. In addition, the material or compound used to construct the mold 100 should not interact with the encapsulant. For example, the mold 100 can be made from a metal, an alloy or a ceramic compound.

The mold 100 includes a contact surface 120 arranged on a lower most surface of the member 111. The contact surface 120 defines a perimeter of a base area that is arranged to surround the semiconductor 30. The contact surface 120 is arranged to contact a compressible layer 150a. The compressible layer 150a is formed by applying a composition in a liquid, liquefiable, or mastic form, which, after application to the substrate, is converted or cured to a compressible solid film. The composition includes a flexible polymer as a binding material. Flexible polymers include an acrylic resin, polyurethane, or polyester. The member 111 forms a cavity 118 that is defined by a left-side surface 113, a right-side surface 117, a rear surface 115 and an upper surface 119. A front surface (not shown in the cross-sectional view) further defines the cavity 118. The cavity 118 is arranged to surround and enclose a volume that receives a semiconductor device 30 attached to the mounting surface 43 of the substrate 40.

During a molding process, as illustrated in FIG. 2B, the mold 100 and the substrate 40 are exposed to external forces. Specifically, the external forces include an external force from above in the direction of the substrate 40 and an external force from below the substrate 40 in the direction of the mold 100. Under these external forces, the mold 100 and the substrate 40 compress the compressible layer 150a (FIG. 2A) on the mounting surface 43 of the substrate 40. The compressed layer 150b forms a seal along the perimeter at the base of the cavity 118. Under adequate environmental conditions, an encapsulant, such as a thermoset plastic, introduced in the cavity 118 flows as a liquid to fill the cavity 118 surrounding the semiconductor device 30. Thereafter, the temperature is adjusted and the encapsulating material or encapsulant is allowed to cure or harden and the mold 100 is removed. An assembly (not shown) remains that includes the semiconductor device 30, the substrate 40, the compressed layer 150b, and the cured encapsulant.

For clarity of illustration and description, equipment and tooling responsible for the upward and downward external forces as shown in FIG. 2B are not shown. Such equipment and tooling are well known and need not be described to understand the improved mold 100 and methods for encapsulating a semiconductor device. For further clarity of illustration and description, one or more ports and one or more devices for introducing the encapsulant and or controlling conditions in the cavity are not shown in FIG. 2A or FIG. 2B. Such ports include but are not limited to channels, vents, sprues and runners. Such devices include but are not limited to plungers, pumps, valves, heaters, coolers, etc. These mechanisms for introducing the encapsulant and controlling a molding process will vary depending on the encapsulant and the molding process. Moreover, these encapsulating materials and mechanisms are well known and need not be described to understand the improved mold 100 and methods for encapsulating a semiconductor device.

It should be understood that while the illustrated embodiment shows a single-cavity mold 100 used in a process of encapsulating a semiconductor 30, such a single-cavity mold 100 is not so limited. For example, a single-cavity mold 100 can be arranged to encapsulate additional semiconductor devices. Furthermore, the single cavity mold can be arranged in configurations that enclose three-dimensional volumes that produce alternative final encapsulation surfaces.

In addition, it should be understood that while the illustrated embodiment shows a compressible layer 150a and a compressed layer 150b that extends beyond the contact surface 120 of a corresponding mold 100, the improved seal formed by the compressed layer 150b between the contact surface 120 and the substrate 40 is not so limited. That is, at any location around the perimeter of a cavity, the compressed layer 150b (as well as the compressible layer 150a) may be narrower, the same or wider than the contact surface 120. Furthermore, errors in registration or alignment between the compressed layer 150b and the contact surface 120 are permissible as long as a seal is formed by the contiguous contact between some portion of the compressed layer 150b and the contact surface 120 over the perimeter of a respective cavity.

Moreover, it should also be understood that while the illustrated embodiment shows a single compressible layer 150a and a single compressed layer 150b, the present seal and methods for encapsulating a semiconductor device are not so limited. For example, as described above, a compressible seal can be formed by one or more additional applications of the composition upon a cured base layer. The base layer and any additional layers may be applied using the same or different thicknesses of the composition. Furthermore, the base layer and any additional layers may be applied using different composition. That is, the base layer and any additional layers can be applied via different composition in any one of a liquid, liquefiable, or mastic form which results a unique sandwich layer consists of different flexible polymer.

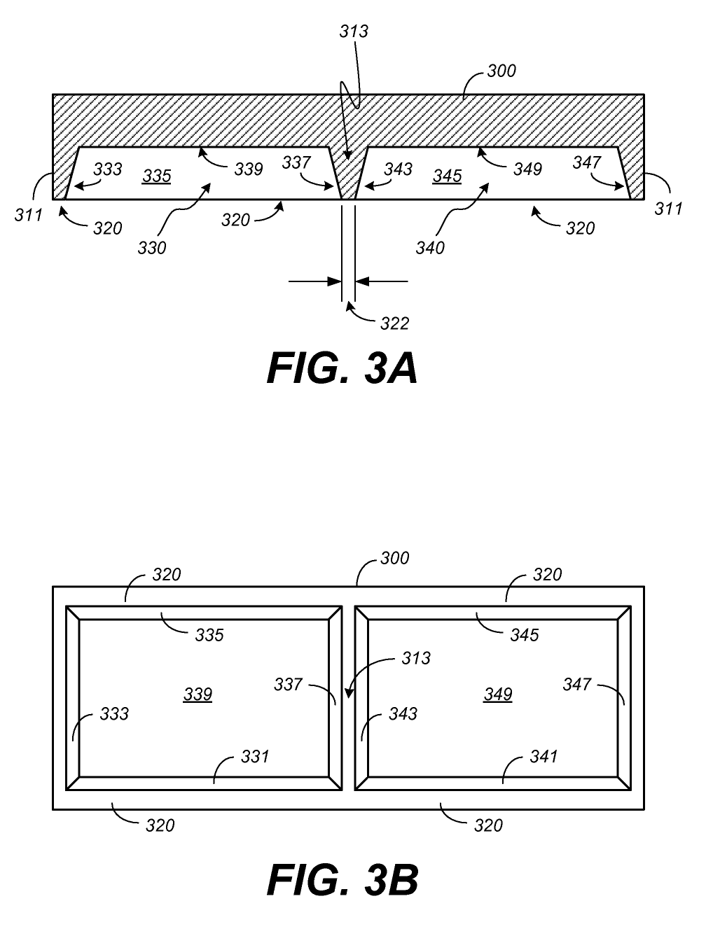

FIGS. 3A and 3B are a cross-sectional view and a bottom-plan view, respectively, of an embodiment of a multiple-cavity mold 300 in accordance with an alternative method for encapsulating semiconductor devices.

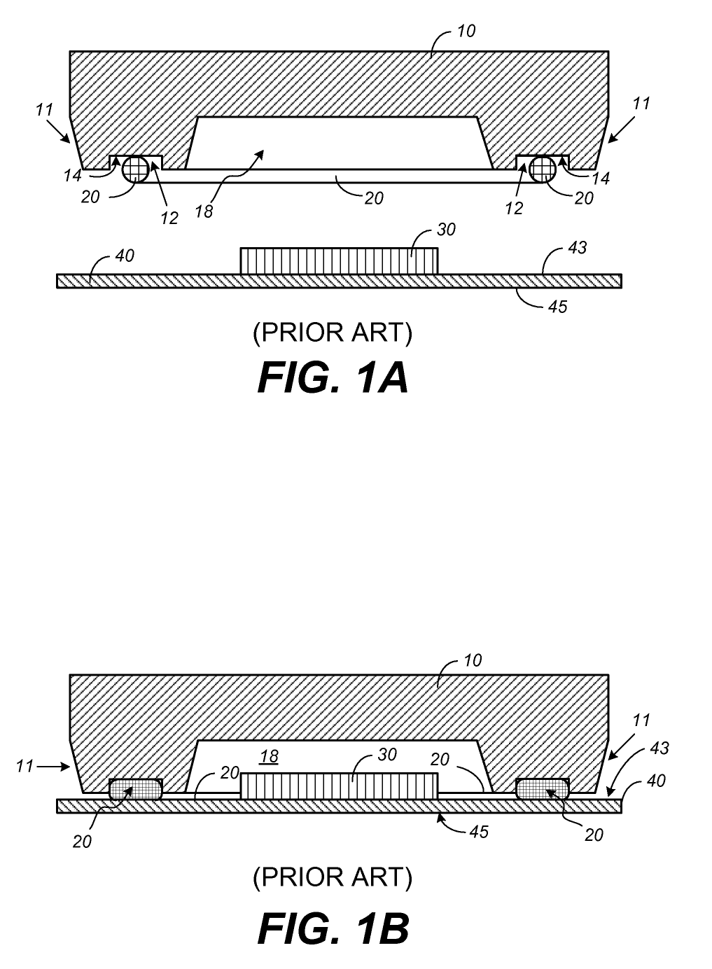

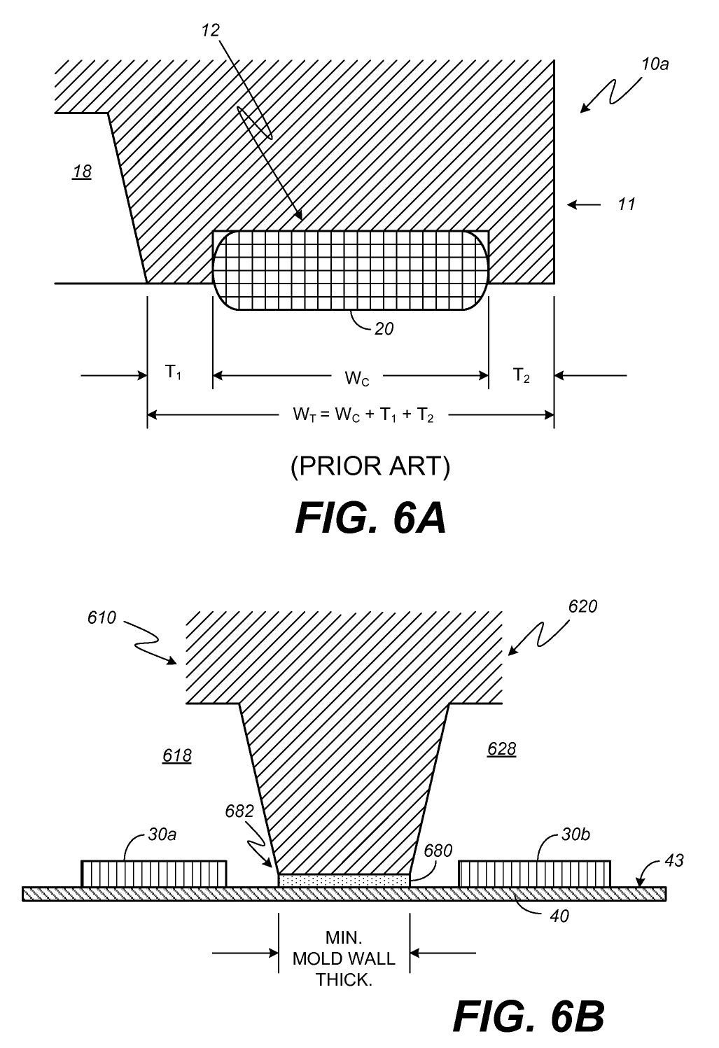

As shown in FIG. 3A, a multiple-cavity mold 300 is arranged with a member 311 that extends from an upper most surface of the mold 300. The mold 300 can be constructed from any material or compound that does not interact with an encapsulant and that retains its shape and strength under expected conditions in a molding process. For example, the mold 300 can be made from a metal, an alloy or a ceramic compound. The member 311 includes a segment 313 that separates a first cavity 330 from a second cavity 340. The segment 313 has a width or distance 322 at its base that is significantly shorter than corresponding walls from prior art molds such as the mold 10 illustrated in FIG. 1A and FIG. 1B. The width or distance 322 between adjacent cavities and of external walls of improved molds can be made significantly shorter than corresponding walls from prior art molds because the wall 311 does not include a channel and is not arranged with a gasket. Accordingly, the improved mold 300 can be arranged to encapsulate devices or assemblies that are arranged closer to one another. That is, the improved mold 300 can encapsulate more devices or assemblies per unit area of a substrate. The capability to encapsulate devices or assemblies with increased densities will be further illustrated and described in association with FIG. 6A, which illustrates a conventional mold with a gasket and FIG. 6B, which shows an embodiment of an improved mold.

The mold 300 (FIGS. 3A and 3B) includes a contact surface 320 arranged on a lower most surface of the member 311. The contact surface 320 defines a perimeter of two base areas that are arranged to surround adjacent semiconductors or adjacent semiconductor assemblies (not shown). The contact layer 320 is arranged to contact a correspondingly arranged compressible layer applied to a mounting surface of a substrate (not shown). The first cavity 330 is defined by left-side surface 333, right-side surface 337, rear surface 335 and upper surface 339. A front surface 331 (FIG. 3B), not shown in the cross-sectional view, further defines the first cavity 330. The first cavity 330 is arranged to surround and enclose a first volume that receives one or more semiconductor devices or assemblies as described above. The second cavity 340 is defined by left-side surface 343, right-side surface 347, rear surface 345 and upper surface 349. A front surface 341 (FIG. 3B), not shown in the cross-sectional view, further defines the first cavity 340. The second cavity 340 is arranged to surround and enclose a second volume that receives one or more semiconductor devices or assemblies as described above.

For clarity of illustration and description, one or more ports and one or more devices for introducing the encapsulant and or controlling conditions in the first and second cavities are not shown in FIG. 3A or FIG. 3B. Such ports include but are not limited to channels, vents, sprues and runners. Such devices include but are not limited to plungers, pumps, valves, heaters, coolers, etc. These mechanisms for introducing the encapsulant and controlling a molding process will vary depending on the encapsulant and the molding process. Moreover, these encapsulating materials and mechanisms are well known and need not be described to understand the improved mold 300 and methods for encapsulating a semiconductor device.

It should be understood that while the illustrated embodiment shows a multiple-cavity mold 300 used in a process for forming two encapsulated assemblies, such a multiple-cavity mold is not so limited. For example, a multiple-cavity mold can be arranged to encapsulate additional devices or assemblies arranged on a substrate as may be desired. By way of example, a multiple-cavity mold can be arranged to encapsulate devices arranged in an M×N array. Where M is an integer representing the number of rows in the array and N is an integer representing the number of columns in the array of devices or assemblies.

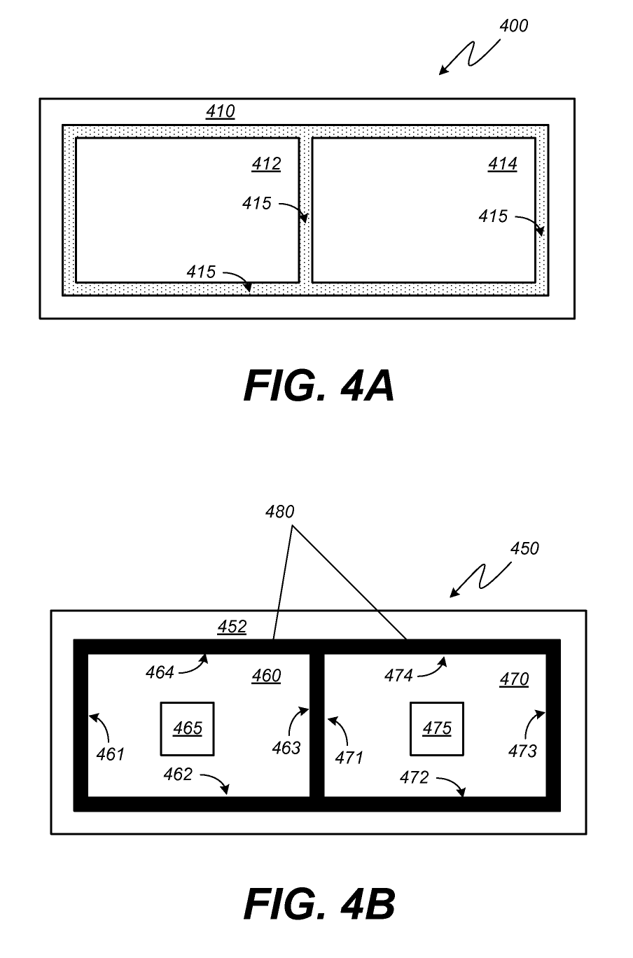

FIG. 4A is a top-plan view of an embodiment of a pattern or stencil 400. The pattern 400 is arranged for use in forming a compressible layer of a cured composition on a substrate of an electro-optical sub-assembly (EOSA) 450 shown in FIG. 4B. The pattern 400 has a thickness or depth (not shown) that corresponds to the desired thickness of the composition to be applied to a surface of a substrate. In an example embodiment, the pattern 400 has a thickness of 25 micrometers. In other embodiments, the pattern 400 can have a thickness or depth that is less than or greater than 25 micrometers. The pattern 400 includes a first mask 410, a second mask 412 and a third mask 414 that are connected to one another via a mesh or screen 415. The mesh or screen 415 is permeable to the composition. That is, the composition is applied to a first side of the pattern 400 and migrated to a second side via screen 415. The first mask 410, second mask 412 and the third mask 414 are non-permeable. That is, the first mask 410, second mask 412 and third mask 414 prevent the composition from flowing or otherwise passing through to the surface of the EOSA 450.

When the pattern 400 is in registration or in alignment with the substrate of the EOSA 450, the first mask 410 prevents the composition from contacting the substrate in an area 452 (FIG. 4B) adjacent to the perimeter of the substrate. The second mask 412 prevents the composition from contacting a first area 460 which accommodates optical transmitter electronics 465 and transmitter mold encapsulation. The optical transmitter electronics 465 normally are consisted of a driver integrated circuit (IC) and light source. The driver IC that accept an electrical signal as its input, process this signal, and uses it to modulate a light source, such as light-emitting diode (LED) or a laser diode, to produce an optical signal capable of being transmitted via an optical transmission medium. The third mask 414 prevents the composition from contacting a second area 470 which houses optical receiver electronics 475 and receiver mold encapsulation. The optical receiver electronics 465 which consists of a photo-sensitive device and receiver IC that receives a modulated light signal as its input and converts the signal to an electrical signal as its output.

FIG. 4B is a top-plan view of an embodiment of a EOSA 450 that has been modified by the application of a composition through the mesh 415 of the pattern 400 introduced in FIG. 4A. As shown, a layer 480 having a width arranged to receive a contact surface (e.g., the contact surface 320) of a corresponding mold (e.g., the mold 300) surrounds the first area 460 and the second area 470. The layer 480 is formed by applying a composition in a liquid, liquefiable, or mastic form, which, after application to a surface of the EOSA 450, is converted or cured to a compressible solid film. The composition includes a flexible polymer as a binding material. Flexible polymers include an acrylic resin, polyurethane, or polyester. When the contact surface 320 is aligned with the layer 480, the inner perimeter of the contact surface 320 and the corresponding legs of the layer 480 define a first base area 460 having a length defined by leg 462 and leg 464 and a width defined by leg 461 and leg 463. A second base area 470 has a length defined leg 472 and leg 474 and a width defined by leg 471 and leg 473.

In the illustrated embodiment, the layer 480 is shown defining rectangular bases or seals with a common leg that separates the first area 460 from the second area 470. In alternative embodiments, each area to be encapsulated is provided with a separate and distinct layer that surrounds the respective area. These separate and distinct layers can be arranged in circles or other shapes having a continuous perimeter, as well as shapes having three legs (i.e., a triangle) or more than four legs as may be desired to encapsulate devices or assemblies.

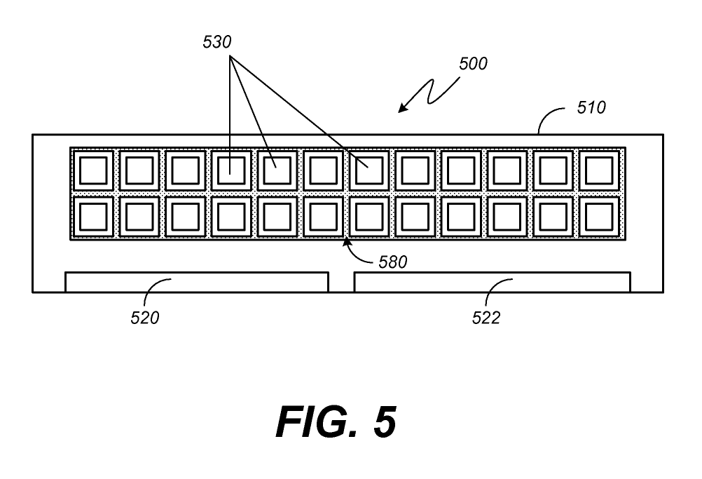

FIG. 5 is a top-plan view of an embodiment of an improved memory module 500. The memory module 500 includes a substrate 510. The substrate 510 includes circuit traces that electrically couple semiconductor dies to a first row of contacts 520 and a second row of contacts 522 formed along an edge of the substrate 510. The semiconductor dies are arranged in an array. The substrate 510 has a layer 580 applied to a surface of the substrate 510. The layer 580 surrounds semiconductor dies that are attached to the substrate 510. The layer 580 is formed by applying a composition in a liquid, liquefiable, or mastic form, which, after application to a surface of the substrate 510, is converted or cured to a compressible solid film. The composition includes a flexible polymer as a binding material. Flexible polymers include an acrylic resin, polyurethane, or polyester. The semiconductor dies may include static random access memory (SRAM), dynamic random access memory (DRAM), synchronous dynamic random access memory (SDRAM), including double data rate SDRAM (DDR-SDRAM), flash-memory and other semiconductor memory circuits.

During a molding process performed during the manufacture of the memory module 500, the layer 580 is compressed by one or more molds configured with respective contact surfaces and recesses to form cavities. The one or more molds are arranged in registration with one or more features of the substrate 510. Features of the substrate 510 suitable for alignment or registration with a mold include but are not limited to an edge of the substrate 510, a hole through the substrate 510, a feature of a device attached to the substrate, a mark or other indicator on a surface of the substrate 510. The one or more molds compress the layer 580 to seal the one or more molds over the semiconductor dies. Once the seals are formed, an encapsulant, such as a thermoset plastic is introduced in a sufficient amount to fill a desired portion of each of the cavities. Thereafter, the environment surrounding the one or more molds and the substrate 510 is controlled to permit the encapsulant to solidify and the one or more molds are removed from the substrate 510. As a result, the semiconductor dies are arranged and encapsulated in an array 530.

In the illustrated embodiment, the memory module 500 includes a rectangular array consisting of two rows of twelve encapsulated cavities with the encapsulant molded into similar shapes. The memory module 500 is not so limited. For example, different arrangements of the semiconductor dies and or other elements to be encapsulated as well as different mold configurations are possible. It should be understood that the number of encapsulated cavities as well as the number and arrangement of semiconductor devices, dies and circuit elements encapsulated therein may vary as may be desired.

FIG. 6A is a partial cross-sectional view of a member 11 of a conventional mold 10a. As described above, the member 11 includes a channel 12. A gasket 20 is fixed in the channel 12. Under compression, a left-side surface and a right-side surface of the channel 12 constrain the gasket 20 from lateral movement along the lower most surfaces of the member 11. As shown in FIG. 6A, this conventional arrangement results in a wall thickness W_{T} that is the sum of a first distance T₁, defined by the cavity 18 and the left-side surface of the channel 12, the width of the channel, W_{C}, and a second distance T₂, defined by the right-side surface of the channel 12 and an exterior surface of the mold 10a.

FIG. 6B is a partial cross-sectional side view of a shared wall of mold 610 constructed in accordance with the improved seal and methods for encapsulating semiconductor devices. The mold 610 forms a first cavity 618 above a mounting surface 43 of the substrate 40 that surrounds a first semiconductor 30a. Similarly, a second cavity 628 is formed above the mounting surface 43 of the substrate 40. A first semiconductor device 30a is enclosed within the first cavity 618. A second semiconductor device 30b is enclosed within the second cavity 628. A seal 682 that prevents the flow of encapsulant from exiting the first cavity 618 is formed when the substrate 40 and the mold 610 compress the layer 680. The layer 680 is formed by applying a composition in a liquid, liquefiable, or mastic form, which, after application to the mounting surface 43 of the substrate 40, is converted or cured to a compressible solid film. The composition includes a flexible polymer as a binding material. Flexible polymers include an acrylic resin, polyurethane, or polyester. The seal 682 also prevents the flow of encapsulant from exiting the second cavity 628 when the substrate 40 and the mold 620 compress the layer 680. The seal 682 entirely surrounds the first semiconductor device 30a as well as the second semiconductor device 30b. It should be clear through comparison with the conventional mold 10a (FIG. 6A) that the mold wall thickness of the mold 610 enables a significantly closer arrangement of the first semiconductor device 30a and the second semiconductor device 30b than could be arranged through assemblies constructed with the conventional mold 10a. Accordingly, a significant improvement in semiconductor device densities can be realized through the use of the improved mold(s) and methods for encapsulating a semiconductor device. For example, in fiber optical transceiver module where its optical transmitter and receiver are required to placed in close proximity for space saving. The benefit can be realized as the optical transmitter and receiver must be encapsulated separately to prevent optical crosstalk causes by the light rays from transmitter impinge on the receiver's photo sensitive device by the means of total internal reflection from the surface of the encapsulant.

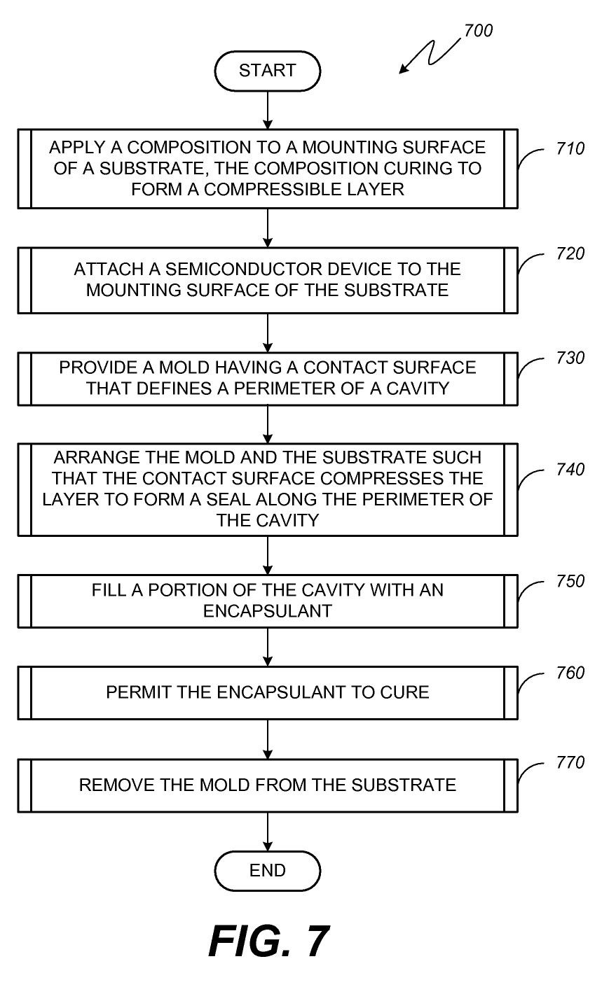

FIG. 7 is a flow diagram illustrating an embodiment of a method for encapsulating a semiconductor device. Method 700 begins with block 710 where a composition is applied to a mounting surface of a substrate. The composition is in a liquid, liquefiable, or mastic form before application. The composition, after being applied to the mounting surface or other surfaces of the substrate, is converted or cured to a compressible solid film. The composition includes a flexible polymer as a binding material. Flexible polymers include an acrylic resin, polyurethane, or polyester. In block 720, a semiconductor device is attached to the mounting surface of the substrate. In block 730, a mold having a contact surface that defines the perimeter of a cavity is provided. Thereafter, as shown in block 740, the mold and the substrate are arranged such that the contact surface compresses the layer to form a seal along the perimeter of the cavity. Next, as indicated in block 750, a portion of the cavity is filled with an encapsulant. In block 760, the encapsulant is allowed to cure or otherwise solidify. Thereafter, as shown in block 770, the mold is removed from the substrate leaving an article of manufacture that includes a compressed layer (e.g., the layer 150b, or the layer 480, the layer 580 or the layer 680) that formed a seal used in formation of the adjacent encapsulant.

Exemplary steps for manufacturing an integrated circuit assembly are illustrated in FIG. 7. The particular sequence of the steps or functions in blocks 710 through 770 is presented for illustration. It should be understood that the order of the steps or functions in blocks 710 through 730 can be performed in any other suitable order.

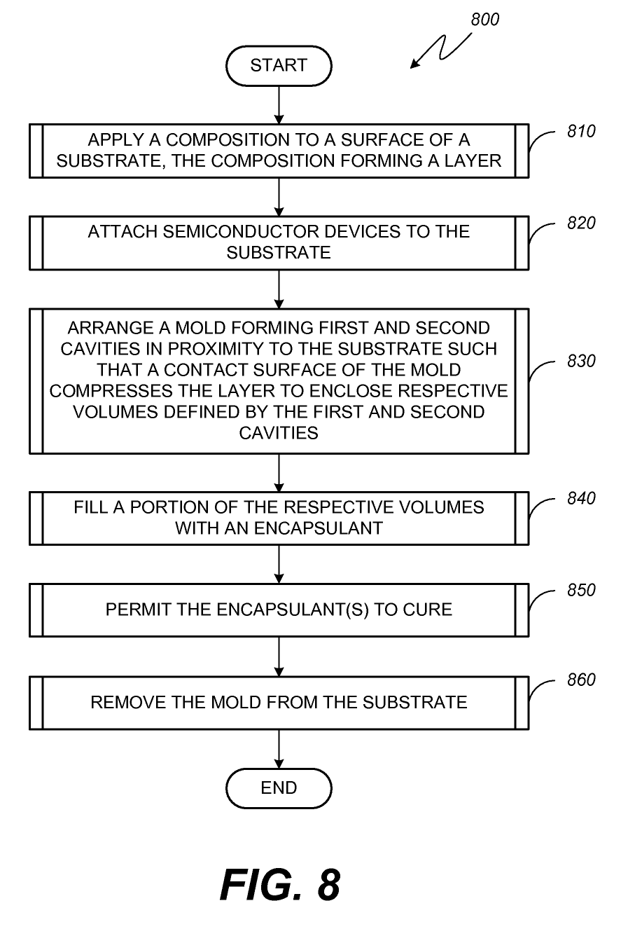

FIG. 8 is a flow diagram illustrating an embodiment of a method for encapsulating semiconductor devices. Method 800 begins with block 810 where a composition, forming a layer, is applied to a surface of a substrate. The composition is in a liquid, liquefiable, or mastic form. The composition, after being applied to a surface of the substrate, is converted or cured to a compressible solid film. The composition includes a flexible polymer as a binding material. Flexible polymers include an acrylic resin, polyurethane, or polyester. In block 820, semiconductor devices are attached to the surface of the substrate. Thereafter, as shown in block 830, a mold forming first and second cavities is arranged in proximity to the substrate such that a contact surface of the mold compresses the layer to seal and enclose respective volumes defined by the first and second cavities. As a result, the first and second cavities surround respective semiconductor devices attached to the substrate. Next, as indicated in block 840, a portion of the respective volumes is filled with an encapsulant. In block 850, the encapsulant is allowed to cure or otherwise form a solid. Thereafter, as shown in block 860, the mold is removed from the substrate leaving an article of manufacture that includes a layer that formed a seal used in formation of the adjacent encapsulant.

The application of the compressible layer on the mounting surface of the substrate eliminates yield loss due to gasket failures, reduces downtime and the costs associated with procuring and installing replacement gaskets. Furthermore, the application of the compressible layer increases yield densities, while still permitting adjacent semiconductor devices to be separately encapsulated, as adjacent semiconductor devices can be arranged closer to each other than previously possible when the devices were encapsulated using a mold that compressed a gasket under a contact surface.

While various embodiments of the integrated circuit assemblies and methods for encapsulating a semiconductor device have been described, it will be apparent to those of ordinary skill in the art that many more embodiments and implementations are possible that are within the scope of this disclosure. Accordingly, the described assemblies and methods are not to be restricted or otherwise limited except in light of the attached claims and their equivalents.

What is claimed is:

1. A method for encapsulating a semiconductor device on a substrate, comprising:
applying a composition that cures to form a compressible layer on a mounting surface of a substrate;
attaching a semiconductor device to the mounting surface of the substrate;
providing a mold having a contact surface that defines a cavity;
arranging the mold and the substrate such that the contact surface compresses the layer to form a seal along a perimeter of the cavity;
filling at least a portion of the volume of the cavity with an encapsulant;
permitting the encapsulant to cure; and
removing the mold from the substrate.

2. The method of claim 1, wherein attaching a semiconductor device comprises providing an electro-optical sub-assembly.

3. The method of claim 2, wherein providing an electro-optical sub-assembly comprises providing an optical transmitter and an optical receiver.

4. The method of claim 3, wherein providing an electro-optical sub-assembly further comprises a contact surface that separates the optical transmitter from the optical receiver.

5. The method of claim 4, wherein an innermost perimeter of the contact surface defines a base area of a respective cavity, each respective cavity arranged to enclose one of the optical transmitter and the optical receiver.

6. The method of claim 1, wherein attaching a semiconductor device comprises providing a memory module.

7. The method of claim 6, wherein providing a memory module comprises arranging at least two dies on the substrate.

8. The method of claim 1, wherein applying a composition to the mounting surface of the substrate comprises arranging a pattern in registration with a feature of the substrate.

9. The method of claim 1, wherein identifying a contact surface of a mold comprises identifying a minimum wall thickness, the minimum wall thickness and the material of the mold determining the ability of the mold to withstand a molding procedure.

10. The method of claim 9, wherein the molding procedure comprises contact pressure, temperature and time.

11. The method of claim 9, wherein the molding procedure comprises an internal pressure difference between adjacent cavities.

12. A method for encapsulating semiconductor devices on a substrate, comprising:
applying a composition to a surface of the substrate, the composition forming a layer;
attaching semiconductor devices on the surface of the substrate;
arranging a mold forming at least a first cavity and a second cavity in proximity to the substrate such that a contact surface of the mold compresses the layer to enclose respective volumes defined by the first and second cavities;
filling at least a portion of the respective volumes of the first and second cavities with an encapsulant;
curing the encapsulant; and
removing the mold from the surface of the substrate.

13. The method of claim 12, wherein arranging the mold and the substrate comprises placing the mold in registration with an electro-optical sub-assembly.

14. The method of claim 13, wherein the electro-optical sub-assembly comprises an optical transmitter and an optical receiver.

15. The method of claim 12, wherein arranging a mold further comprises selecting first and second semiconductor devices comprising memory elements.

16. The method of claim 12, wherein applying a composition comprises arranging a pattern in registration with a feature of the substrate, the pattern comprising a mask that prevents the material from contacting select areas of the substrate and the first and second semiconductor devices.

17. The method of claim 12, wherein arranging a mold forming at least a first cavity and a second cavity comprises identifying a minimum wall thickness, the minimum wall thickness limited by the ability of the mold to withstand a molding environment.

18. The method of claim 17, wherein the molding environment comprises changing pressure and temperature.

19. An electro-optical assembly prepared by a process comprising the steps of:
applying a composition to a surface of the substrate, the composition forming a layer;
arranging a mold forming at least a first cavity and a second cavity in proximity to the substrate such that a contact surface of the mold compresses the layer to enclose respective volumes defined by the first and second cavities and that surrounds respective first and second semiconductor devices attached to the substrate;
filling at least a portion of the respective volumes of the first and second cavities with an encapsulant;
curing the encapsulant; and
removing the mold from the surface of the substrate.

20. A memory device prepared by a process comprising the steps of:
applying a composition to a surface of the substrate, the composition curing to form a compressible layer;
arranging a mold forming at least a first cavity and a second cavity in proximity to the substrate such that a contact surface of the mold compresses the layer to enclose respective volumes defined by the first and second cavities and that surrounds respective first and second semiconductor devices attached to the substrate;
filling at least a portion of the respective volumes of the first and second cavities with an encapsulant;
curing the encapsulant; and
removing the mold from the surface of the substrate.

21. An assembly having an encapsulated semiconductor device prepared by a process comprising the steps of:
attaching a semiconductor device to a substrate having a mounting surface;
identifying a contact surface of a mold, the contact surface defining a perimeter of a cavity;
generating a pattern having an opening arranged to receive the contact surface when the pattern is in registration with the contact surface;
using the pattern to apply a composition to the mounting surface of the substrate, wherein the composition cures to form a compressible layer;
arranging the mold and the substrate such that the contact surface compresses the layer to form a seal;
filling at least a portion of the volume of the cavity with an encapsulant;
permitting the encapsulant to cure; and
removing the mold from the substrate.
